(19) United States
(12) Patent Application Publication
(10) Pub. No.: US 2026/0307399 A1
(43) Pub. Date: Oct. 8, 2026

(54) INKJET PRINTING DEVICE AND INKJET PRINTING METHOD USING THE INKJET PRINTING DEVICE

(71) Applicant: Samsung Display Co., LTD., Yongin-si (KR)

(72) Inventors: KATSUYUKI HIRATO, Yongin-si (KR); YU KONTA, Yongin-si (KR); CHEONG-WAN MIN, Yongin-si (KR)

(21) Appl. No.: 19/548,398

(22) Filed: Feb. 24, 2026

(30) Foreign Application Priority Data
Apr. 8, 2025 (KR) 10-2025-0045631

(51) Int. Cl. B41J 11/00; B41M 7/00

(52) U.S. Cl. CPC B41J 11/002; B41M 7/0018; B41M 7/009

(57) ABSTRACT

An inkjet printing device includes an inkjet head which discharges an ink onto a substrate and an injection unit which discharges a solvent onto the substrate in association with controlling a vapor pressure around the ink discharged onto the substrate.

### CROSS-REFERENCE TO RELATED APPLICATION

This application claims priority to Korean Patent Application No. 10-2025-0045631, filed on Apr. 8, 2025, and all the benefits accruing therefrom under 35 U.S.C. §119, the content of which in its entirety is herein incorporated by reference.

### BACKGROUND

### 1. Field

Embodiments relate to an inkjet printing device and an inkjet printing method using the inkjet printing device.

### 2. Description of the Related Art

In a process of manufacturing a display device, an inkjet printing device may be used. For example, in order to form a light-emitting layer included in the display device, ink for forming the light-emitting layer may be discharged onto a substrate through the inkjet printing device.

The ink discharged onto the substrate may be dried, and drying speed of the ink may differ based on when the ink was discharged and the area onto which the ink was discharged. A deviation in the drying speed causes uneven drying of the ink, and color tone or emission efficiency of the display device may deteriorate.

### SUMMARY

Embodiments provide an inkjet printing device.

Embodiments provide an inkjet printing method using the inkjet printing device.

An inkjet printing device according to embodiments includes an inkjet head which discharges an ink onto a substrate, and an injection unit which discharges a solvent onto the substrate in association with controlling a vapor pressure around the ink discharged onto the substrate.

In an embodiment, a nozzle which discharges the solvent may be formed in the injection unit.

In an embodiment, a slit which discharges the solvent may be formed in the injection unit.

In an embodiment, a pore which discharges the solvent may be formed in the injection unit.

In an embodiment, the injection unit may surround a side of the inkjet head.

In an embodiment, the inkjet printing device may further include a solvent storage unit which stores the solvent, a vapor pressure increasing unit which increases a vapor pressure of the solvent stored in the solvent storage unit, and a transfer unit to transfer the solvent having the increased vapor pressure to the injection unit.

In an embodiment, the vapor pressure increasing unit may apply heat to the solvent.

In an embodiment, the vapor pressure increasing unit may apply an ultrasonic wave to the solvent.

In an embodiment, the transfer unit may be a fan or a pump.

In an embodiment, the solvent in a liquid state may be stored in the solvent storage unit, and the solvent in a gaseous state may be transferred to the injection unit.

In an embodiment, a temperature of the injection unit may be higher than or equal to a temperature of the substrate.

In an embodiment, the inkjet printing device may further include a recovery unit having a temperature lower than a temperature of the substrate and which recovers the solvent by condensation.

In an embodiment, the inkjet printing device may further include a vapor pressure measurement sensor which measures a vapor pressure around the ink discharged onto the substrate, and a solvent control unit which controls an amount of the solvent provided to the injection unit based on the measured vapor pressure.

In an embodiment, the inkjet printing device may further include a ventilation unit which ventilates a chamber in which the substrate is positioned.

An inkjet printing method according to embodiments includes discharging an ink onto a first outer portion of a substrate, and discharging a solvent onto the substrate in association with controlling a vapor pressure around the ink discharged onto the substrate while the ink is discharged onto the first outer portion of the substrate.

In an embodiment, the inkjet printing method may further include discharging the ink onto a center portion of the substrate. The solvent may not be discharged while the ink is discharged onto the center portion of the substrate.

In an embodiment, the inkjet printing method may further include discharging the ink onto a second outer portion of the substrate. The solvent may not be discharged while the ink is discharged onto the second outer portion of the substrate.

In an embodiment, the inkjet printing method may further include discharging the ink onto a center portion of a substrate, and discharging the solvent onto the substrate while the ink is discharged onto the center portion of the substrate. An amount of the solvent discharged while the ink is discharged onto the center portion of the substrate may be less than an amount of the solvent discharged while the ink is discharged onto the first outer portion of the substrate.

In an embodiment, the inkjet printing method may further include discharging the ink onto a second outer portion of a substrate, and discharging the solvent onto the substrate while the ink is discharged onto the second outer portion of the substrate. An amount of the solvent discharged while the ink is discharged onto the second outer portion of the substrate may be less than the amount of the solvent discharged while the ink is discharged onto the center portion of the substrate.

In an embodiment, a chamber in which the substrate is positioned may not be ventilated while the ink is discharged.

The inkjet printing device according to the embodiments may include the inkjet head that discharges the ink and the injection unit that discharges the solvent. The injection unit may discharge the solvent onto the substrate while the inkjet head discharges the ink onto the substrate. Accordingly, the vapor pressure around the ink discharged onto the substrate may be controlled, and the drying speed of the ink may be controlled.

For example, a period in which the solvent is discharged and an amount of the discharged solvent may be set based on the vapor pressure around the ink discharged onto the substrate (or a vapor pressure in the chamber). Accordingly, the deviation in drying speed of the ink discharged onto the substrate may decrease, and the uneven drying of the ink may be improved.

### BRIEF DESCRIPTION OF THE DRAWINGS

Illustrative, non-limiting embodiments will be more clearly understood from the following detailed description taken in conjunction with the accompanying drawings.

FIG. 1 is a diagram for describing an inkjet printing device according to an embodiment.

FIG. 2 is a diagram for describing an example of a vapor pressure increasing unit included in the inkjet printing device of FIG. 1.

FIG. 3 is a diagram for describing an example of the vapor pressure increasing unit included in the inkjet printing device of FIG. 1.

FIG. 4 is a diagram for describing an example of the vapor pressure increasing unit included in the inkjet printing device of FIG. 1.

FIG. 5 is a diagram for describing an example of the vapor pressure increasing unit included in the inkjet printing device of FIG. 1.

FIG. 6 is a diagram for describing an example of an injection unit included in the inkjet printing device of FIG. 1.

FIG. 7 is a diagram for describing an example of the injection unit included in the inkjet printing device of FIG. 1.

FIG. 8 is a diagram for describing an example of the injection unit included in the inkjet printing device of FIG. 1.

FIGS. 9-11 are diagrams for describing an inkjet printing method according to an embodiment.

FIGS. 12-14 are diagrams for describing an inkjet printing method according to an embodiment.

FIG. 15 is a diagram for describing an inkjet printing device according to an embodiment.

FIG. 16 is a diagram for describing an inkjet printing device according to an embodiment.

FIG. 17 is a cross-sectional view for describing a display device formed by the inkjet printing device and the inkjet printing method.

FIG. 18 is a block diagram illustrating an electronic device according to an embodiment.

FIG. 19 is a diagram illustrating electronic devices according to embodiments.

### DETAILED DESCRIPTION

Hereinafter, an inkjet printing device and an inkjet printing method according to embodiments of the present disclosure will be described in more detail with reference to the accompanying drawings. The same or similar reference numerals will be used for the same elements in the accompanying drawings.

Embodiments supported by the present disclosure will now be described more fully hereinafter with reference to the accompanying drawings, in which one or more example embodiments are illustrated. Aspects supported by the present disclosure may, however, be embodied in different forms and should not be construed as limited to the embodiments set forth herein. Rather, these example embodiments are provided so that this disclosure will be thorough and complete, and will fully convey the scope of example aspects of the invention to those skilled in the art.

Terms such as, for example, first, second, and the like may be used to describe various components, but the components should not be limited by the terms. The terms as used herein may distinguish one component from other components and are not to be limited by the terms. For example, without departing the scope of the present disclosure, a first component may be referred to as a second component, and similarly, the second component may also be referred to as the first component. The terms of a singular form may include plural forms unless otherwise specified.

The terminology used herein is for the purpose of describing particular embodiments and is not intended to be limiting. As used herein, “a,” “an,” “the,” and “at least one” do not denote a limitation of quantity, and are intended to include both the singular and plural, unless the context clearly indicates otherwise. For example, “an element” has the same meaning as “at least one element," unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, or components.

The term “substantially,” as used herein, means approximately or actually. The term “substantially equal” means approximately or actually equal. The term “substantially the same” means approximately or actually the same. The term “substantially identical” means approximately or actually identical. The term “substantially perpendicular” means approximately or actually perpendicular.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Embodiments are described herein with reference to cross section illustrations that are schematic illustrations of example embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as "A or B”, "at least one of A and B”, "at least one of A or B”, "A, B, or C”, "at least one of A, B, and C”, and "at least one of A, B, or C”, may include any one of, or all possible combinations of the items enumerated together in a corresponding one of the phrases.

It is to be understood that if an element (e.g., a first element) is referred to, with or without the term "operatively" or "communicatively", as "coupled with”, "coupled to”, "connected with”, or "connected to" another element (e.g., a second element), it means that the element may be coupled with the other element directly (e.g., wiredly), wirelessly, or via a third element.

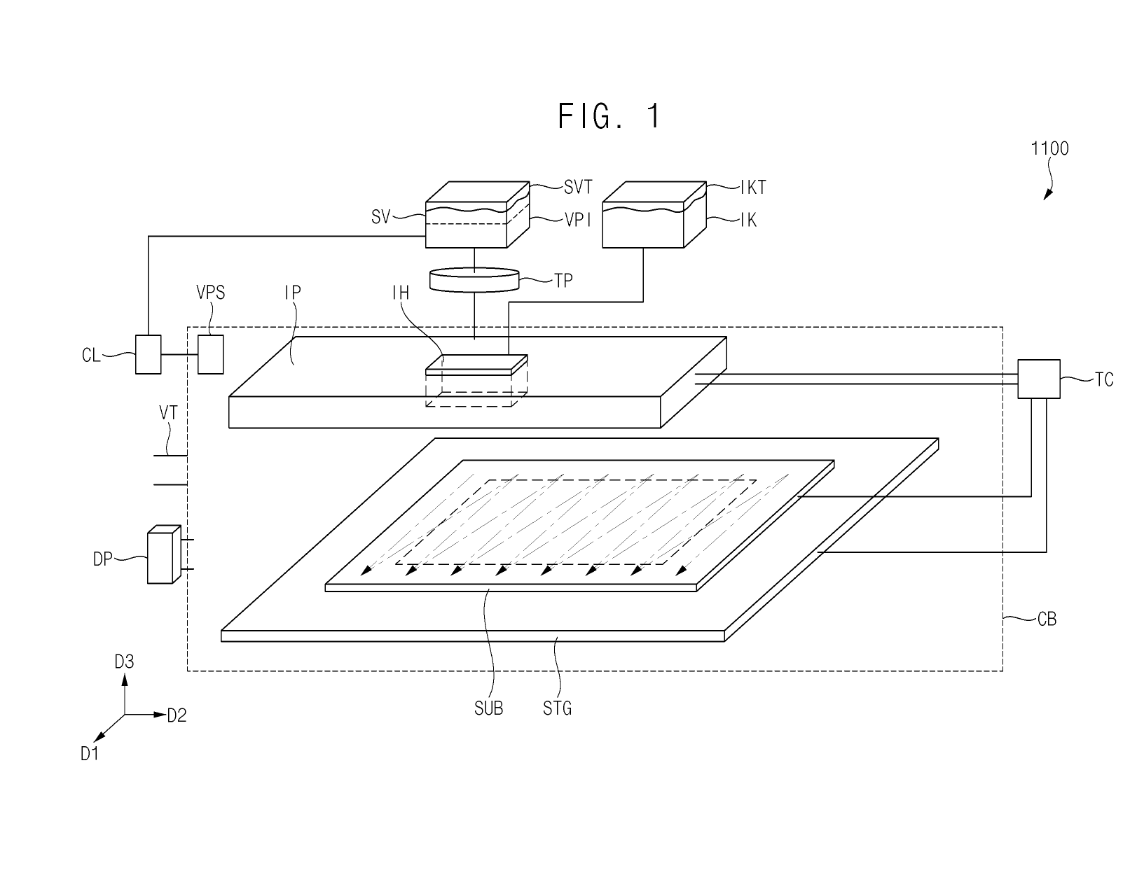

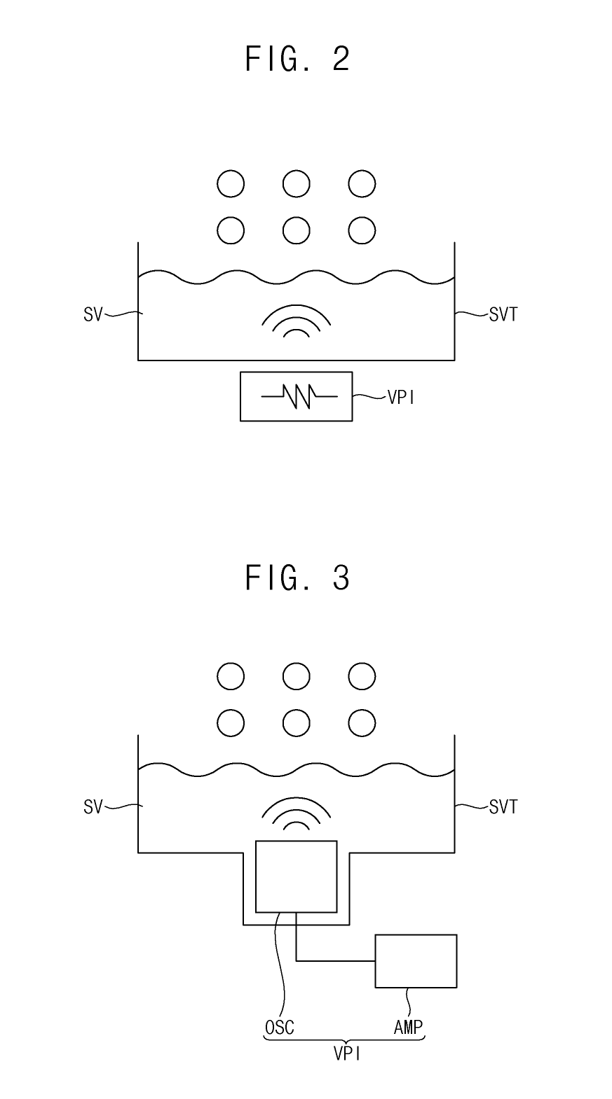

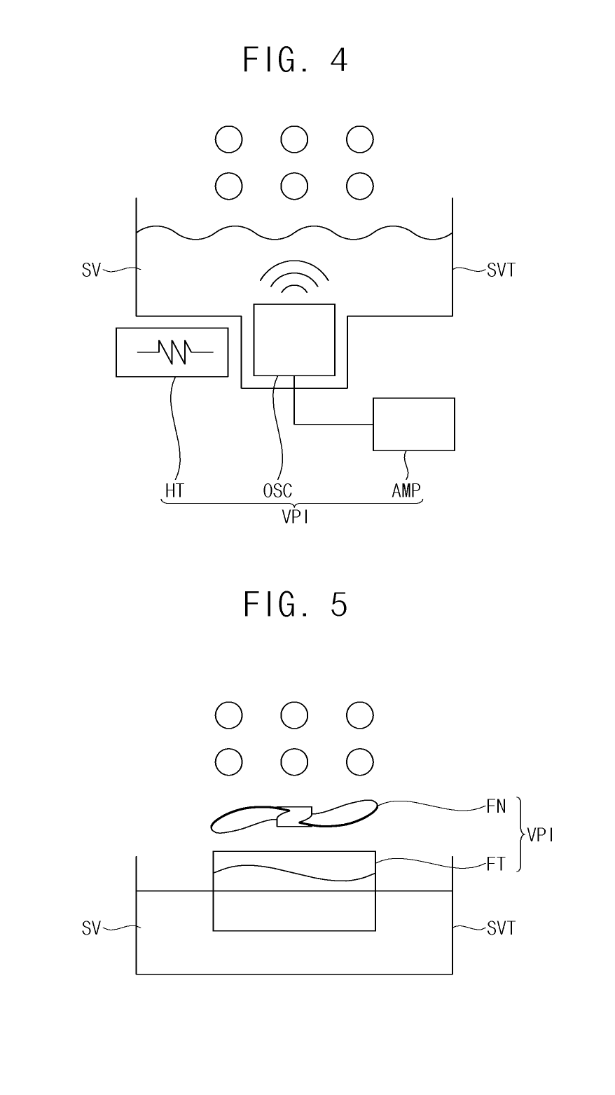

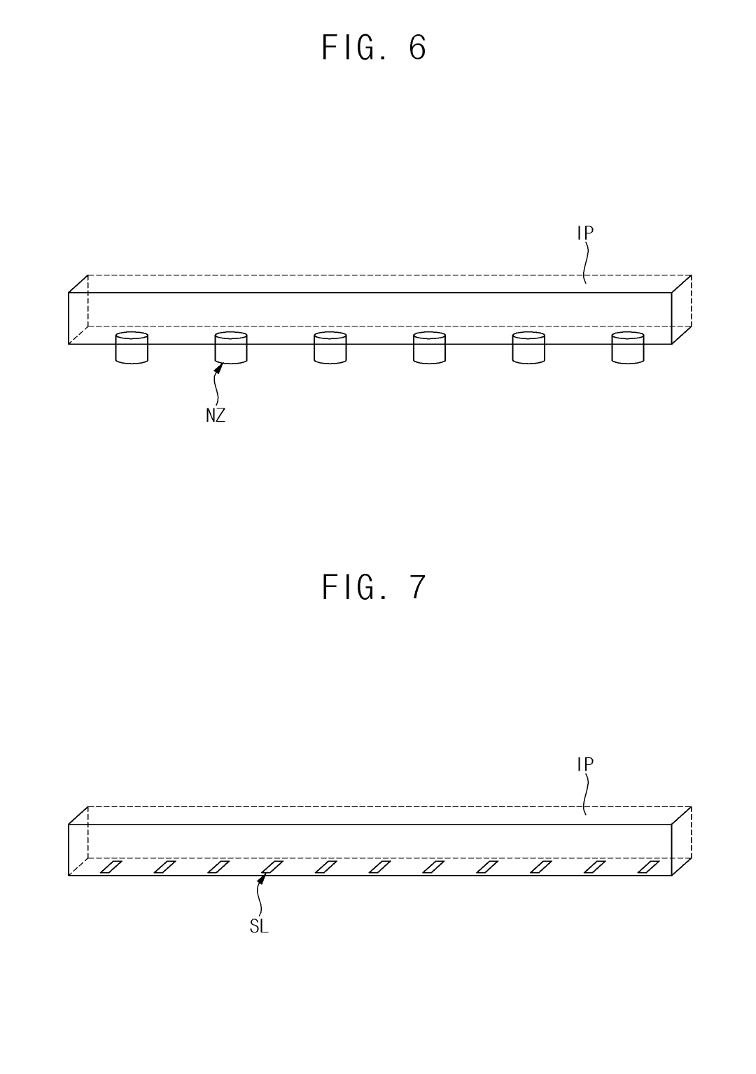

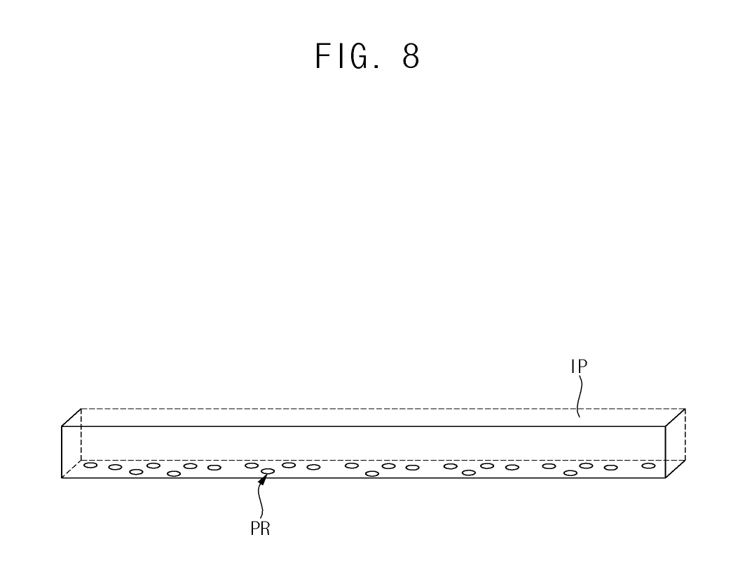

FIG. 1 is a diagram for describing an inkjet printing device according to an embodiment. FIG. 2 is a diagram for describing an example of a vapor pressure increasing unit included in the inkjet printing device of FIG. 1. FIG. 3 is a diagram for describing an example of the vapor pressure increasing unit included in the inkjet printing device of FIG. 1. FIG. 4 is a diagram for describing an example of the vapor pressure increasing unit included in the inkjet printing device of FIG. 1. FIG. 5 is a diagram for describing an example of the vapor pressure increasing unit included in the inkjet printing device of FIG. 1. FIG. 6 is a diagram for describing an example of an injection unit included in the inkjet printing device of FIG. 1. FIG. 7 is a diagram for describing an example of the injection unit included in the inkjet printing device of FIG. 1. FIG. 8 is a diagram for describing an example of the injection unit included in the inkjet printing device of FIG. 1.

Referring to FIG. 1, an inkjet printing device 1100 according to an embodiment of the present disclosure may include an ink storage unit IKT, an inkjet head IH, a solvent storage unit SVT, a vapor pressure increasing unit VPI, a transfer unit TP, an injection unit IP, a recovery unit DP, a temperature control unit TC, a vapor pressure measurement sensor VPS, a solvent control unit CL, and a ventilation unit VT.

A stage STG may be positioned in a chamber CB, and a substrate SUB may be arranged on the stage STG. The stage STG may transport the substrate SUB. The inkjet head IH may move in a first direction D1 and a second direction D2 intersecting the first direction D1, and may be arranged above the substrate SUB. The inkjet printing device 1100 may discharge ink IK to the substrate SUB, and may discharge solvent SV onto the substrate SUB.

The ink storage unit IKT may store the ink IK, and may be connected to the inkjet head IH. The ink storage unit IKT may transfer the ink IK to the inkjet head IH. For example, the ink IK may be any ink used in a process of manufacturing a display device. In an embodiment, the ink IK may be an organic light-emitting material used in a light-emitting layer included in the display device. In an embodiment, the ink IK may be a selective light-blocking material used in a color filter included in the display device.

The inkjet head IH may be arranged above the substrate SUB, and may discharge the ink IK to the substrate SUB. For example, a plurality of nozzles and a discharging control unit connected to the nozzles may be formed in the inkjet head IH, and the ink IK may be discharged from the nozzles based on a control of the discharging control unit.

In an embodiment, the inkjet head IH may move in the first direction D1 and the second direction D2. For example, the inkjet head IH may repeat an operation of moving in the first direction D1 and discharging the ink IK.

The solvent storage unit SVT may store the solvent SV, and may be connected to the injection unit IP through the transfer unit TP. The solvent storage unit SVT may transfer the solvent SV to the injection unit IP.

In an embodiment, the solvent SV may be any one of inks used in the inkjet printing device 1100. For example, the solvent SV may be an ink having the highest vapor pressure among the inks.

The vapor pressure increasing unit VPI may increase a vapor pressure of the solvent SV stored in the solvent storage unit SVT. For example, the solvent SV in a liquid state may be stored in the solvent storage unit SVT, and the vapor pressure increasing unit VPI may vaporize the solvent SV. Accordingly, the solvent SV in a gaseous state may be transferred to the injection unit IP.

Referring to FIGS. 2-5, the vapor pressure increasing unit VPI may be implemented as an appropriate means capable of increasing the vapor pressure of the solvent SV. In an embodiment, as illustrated in FIG. 2, the vapor pressure increasing unit VPI may apply heat to the solvent SV. For example, the vapor pressure increasing unit VPI may include a heater that generates heat. In an embodiment, as illustrated in FIG. 3, the vapor pressure increasing unit VPI may apply ultrasonic waves to the solvent SV. For example, the vapor pressure increasing unit VPI may include an oscillator OSC that generates the ultrasonic waves and an amplifier AMP that drives the oscillator OSC. In an embodiment, as illustrated in FIG. 4, the vapor pressure increasing unit VPI may apply heat and ultrasonic waves to the solvent SV. For example, the vapor pressure increasing unit VPI may include an oscillator OSC, an amplifier AMP, and a heater HT. In an embodiment, as illustrated in FIG. 5, the vapor pressure increasing unit VPI may include a filter FT that absorbs the solvent SV and a fan FN that blows air to the filter FT to evaporate the solvent SV. However, embodiments of the present disclosure are not limited thereto.

Referring to FIG. 1 again, in an embodiment, the transfer unit TP may transfer the solvent SV with increased vapor pressure to the injection unit IP. For example, the transfer unit TP may be a blower for transferring the solvent SV in a gaseous state, and may be implemented as a fan or a pump.

In an embodiment, the injection unit IP may be arranged around the inkjet head IH. For example, the injection unit IP may surround a side of the inkjet head IH.

In an embodiment, the injection unit IP may discharge the solvent SV onto the substrate SUB. For example, the solvent SV may be a gaseous solvent with increased vapor pressure. Accordingly, the vapor pressure around the ink IK discharged onto the substrate SUB may be controlled, and the drying speed of the ink IK may be controlled.

Referring to FIGS. 6-8, a means for discharging the solvent SV may be appropriately formed in the injection unit IP. In an embodiment, as illustrated in FIG. 6, nozzles NZ that discharge the solvent SV may be formed in the injection unit IP. In an embodiment, as illustrated in FIG. 7, slits SL that discharge the solvent SV may be formed in the injection unit IP. In an embodiment, as illustrated in FIG. 8, the injection unit IP may include porous members, and pores PR may be formed in the injection unit IP.

Referring to FIG. 1 again, the recovery unit DP may recover the solvent SV. For example, the recovery unit DP may have a low temperature capable of condensing the solvent SV. Accordingly, the recovery unit DP may recover the solvent SV by condensing the solvent SV. In an embodiment, the recovery unit DP may be installed in a passage through which the solvent SV is returned. In an embodiment, the recovery unit DP may be installed around the substrate SUB.

The temperature control unit TC may measure a temperature of the substrate SUB and a temperature of the stage STG, and may control a temperature of the injection unit IP. For example, the temperature control unit TC may control the temperature of the injection unit IP to be relatively high. Specifically, the temperature of the injection unit IP may be higher than or equal to the temperature of the substrate SUB and the temperature of the stage STG. As the temperature of the injection unit IP maintains relatively high, the solvent SV may not condense in a portion where the solvent SV is discharged.

In an embodiment, the vapor pressure measurement sensor VPS may measure the vapor pressure around the ink IK discharged onto the substrate SUB (or, the vapor pressure in the chamber CB).

In an embodiment, the solvent control unit CL may control the amount of the solvent SV provided to the injection unit IP based on the vapor pressure measured by the vapor pressure measurement sensor VPS. For example, the solvent control unit CL may control the vapor pressure increasing unit VPI, and the amount of the solvent SV may be controlled based on the operation of the vapor pressure increasing unit VPI.

The ventilation unit VT may ventilate the chamber CB. In an embodiment, before an inkjet printing process in which the ink IK is discharged starts, the ventilation unit VT may ventilate the chamber CB. In an embodiment, after the inkjet printing process is finished, the ventilation unit VT may ventilate the chamber CB.

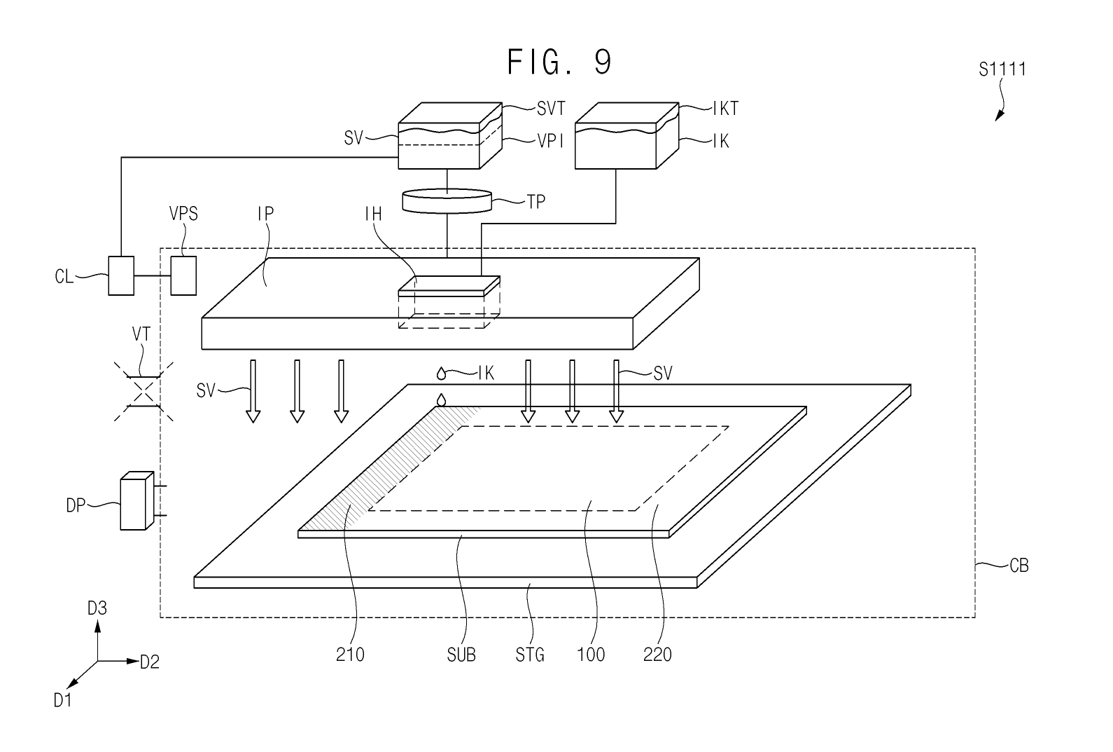

FIGS. 9-11 are diagrams for describing an inkjet printing method according to an embodiment.

In the descriptions of the method and processes herein, the operations may be performed in a different order than the order shown and/or described, or the operations may be performed in different orders or at different times. Certain operations may also be left out of the flowcharts, one or more operations may be repeated, or other operations may be added. Passive descriptions of steps such as, for example, “may be arranged,” “may be discharged,” “may be controlled,” and the like include active methods, processes, and techniques for arranging, discharging, controlling, and the like in accordance with example aspects described herein.

Referring to FIG. 9, the substrate SUB may be divided into a center portion 100, a first outer portion 210, and a second outer portion 220. The center portion 100 is an area corresponding to a center of the substrate SUB, and the first outer portion 210 and the second outer portion 220 may be areas adjacent to the center portion 100 and corresponding to outer portions of the substrate SUB. Further, the first outer portion 210 may be defined on one side of the center portion 100, and the second outer portion 220 may be defined on the other side of the center portion 100. Accordingly, the inkjet printing process may be performed in the order of the first outer portion 210, the center portion 100, and the second outer portion 220.

The inkjet head IH may be arranged above the first outer portion 210, and may discharge the ink IK while moving along the first direction D1 (S1111). Accordingly, the ink IK may be discharged onto the first outer portion 210.

In an embodiment, while the ink IK is discharged onto the first outer portion 210, the solvent SV may be discharged from the injection unit IP (S1111). As the solvent SV is discharged, the vapor pressure around the ink IK discharged onto the first outer portion 210 may be controlled. For example, the amount of the solvent SV which is discharged may be increased, and the vapor pressure around the ink IK discharged onto the first outer portion 210 may increase. Accordingly, the drying speed of the ink IK may decrease.

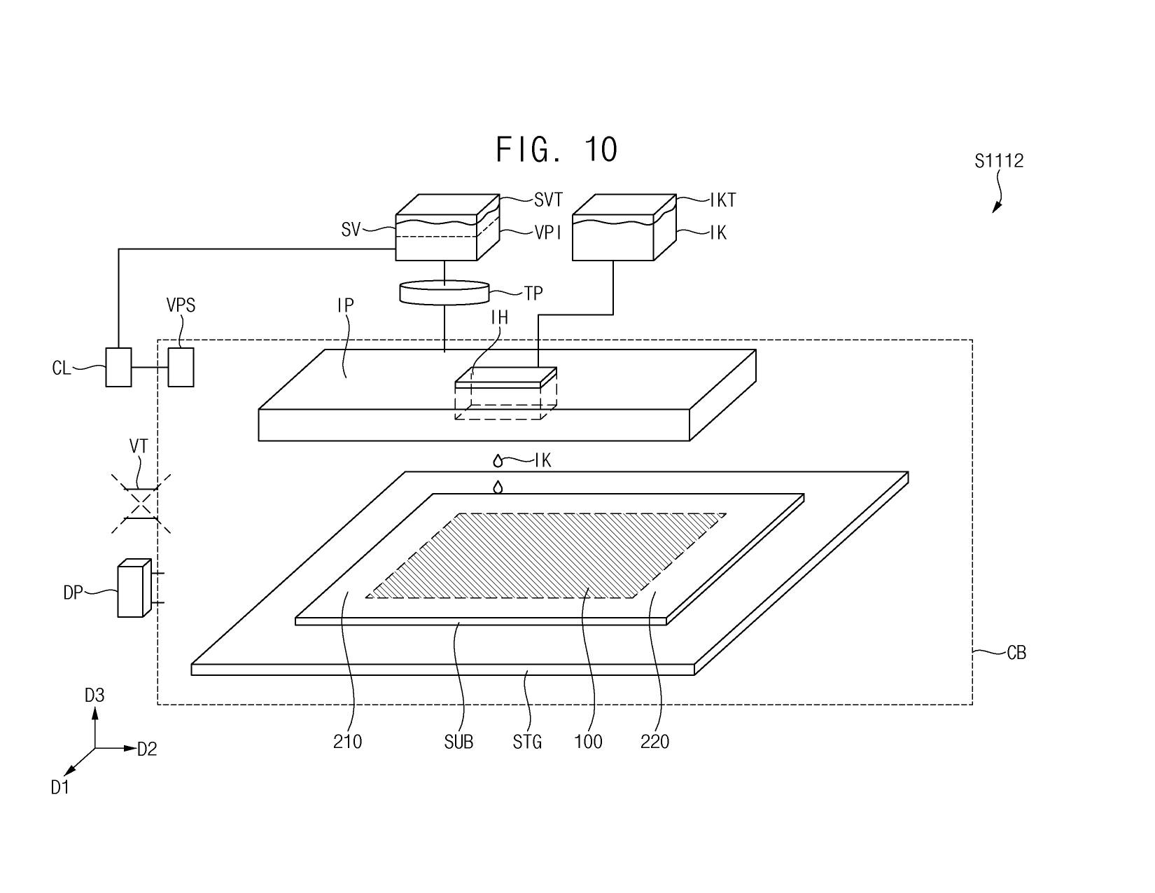

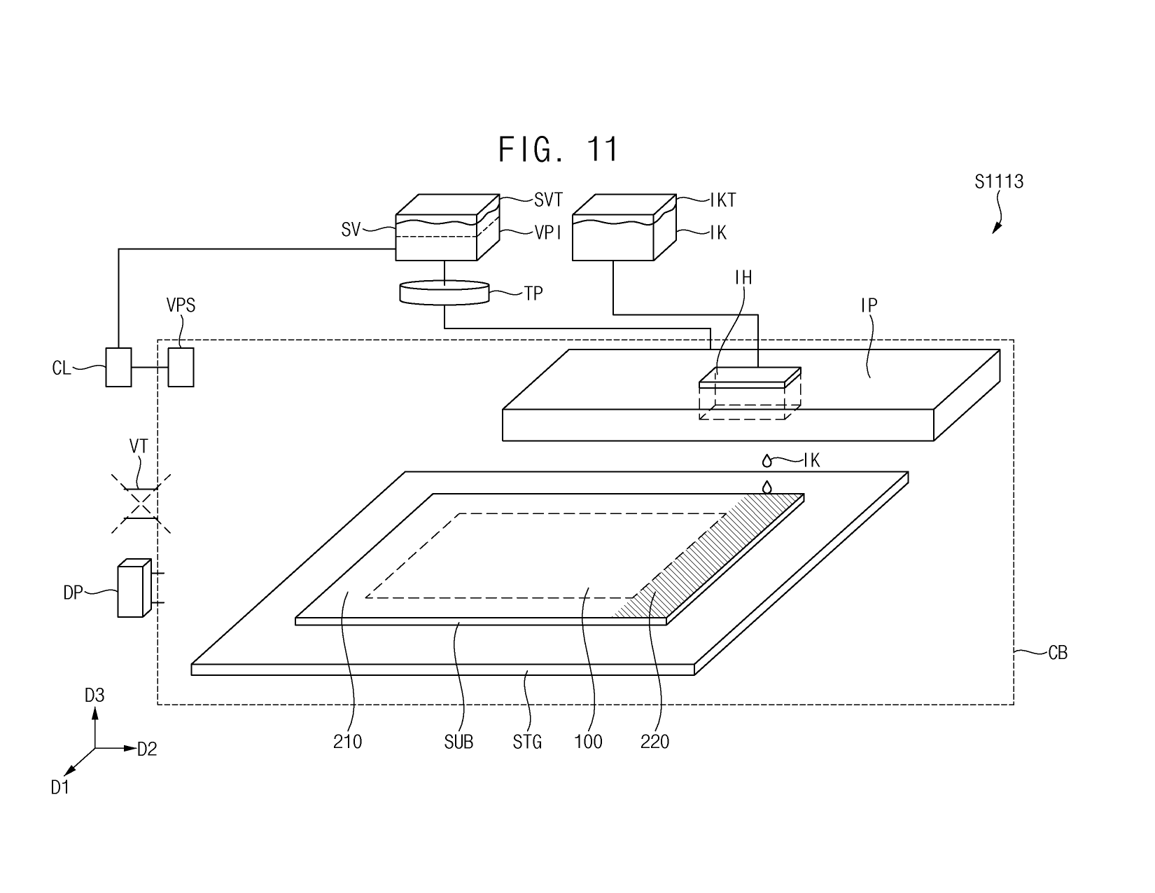

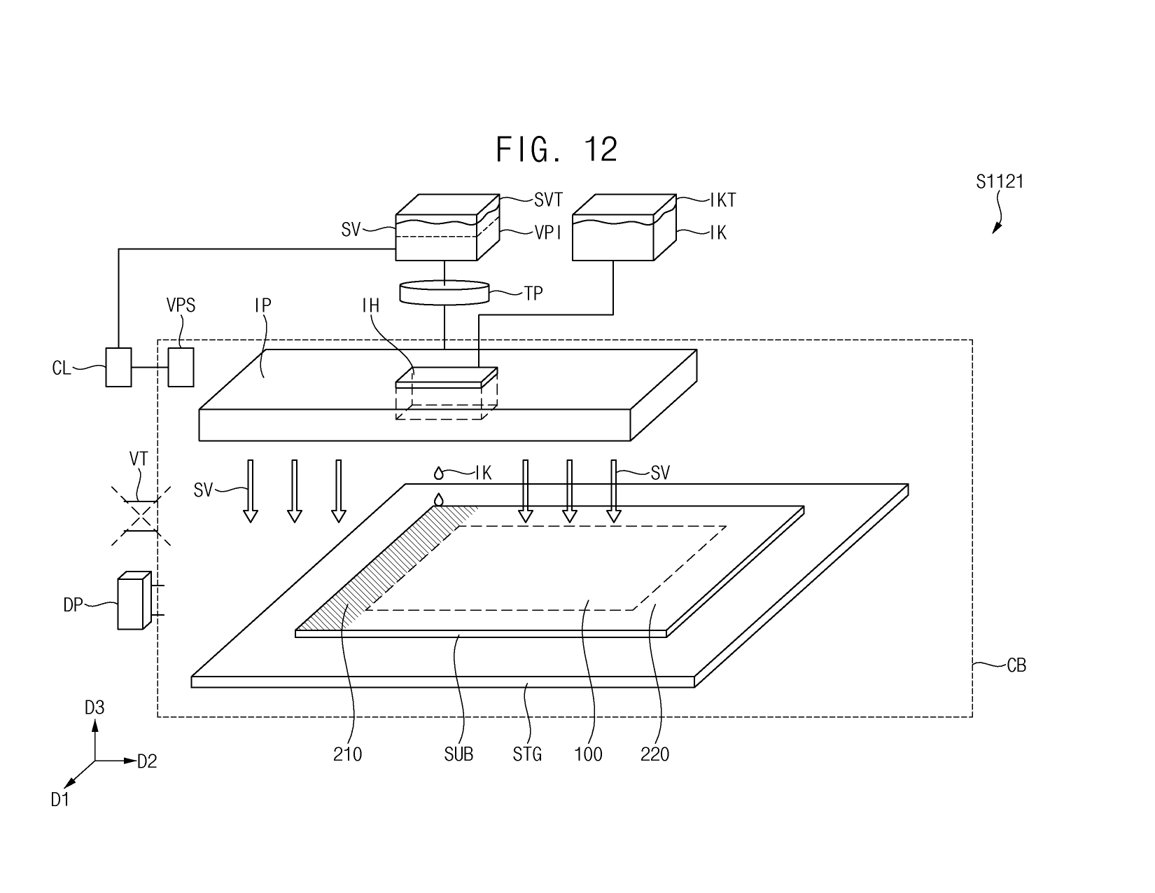

Referring to FIG. 10, after the ink IK is discharged onto the first outer portion 210, the inkjet head IH may be arranged above the center portion 100, and may discharge the ink IK while moving along the first direction D1 (S1112). Accordingly, the ink IK may be discharged onto the center portion 100.

In an embodiment, while the ink IK is discharged onto the center portion 100, the solvent SV may not be discharged from the injection portion IP (S1112).

Referring to FIG. 11, after the ink IK is discharged onto the center portion 100, the inkjet head IH may be arranged above the second outer portion 220, and may discharge the ink IK while moving along the first direction D1 (S1113). Accordingly, the ink IK may be discharged onto the second outer portion 220.

In an embodiment, while the ink IK is discharged onto the second outer portion 220, the solvent SV may not be discharged from the injection unit IP (S1113).

While the ink IK is discharged from the inkjet head IH, the solvent SV may be selectively discharged.

For example, the ink IK discharged onto the first outer portion 210 may have a relatively fast drying speed since no other ink discharged around the ink IK exists. Accordingly, in order to control the drying speed of the ink IK discharged onto the first outer portion 210, the solvent SV may be discharged while the ink IK is discharged onto the first outer portion 210. As the solvent SV is discharged onto the first outer portion 210, the vapor pressure around the ink IK discharged onto the first outer portion 210 may increase. Accordingly, the drying speed of the ink IK may decrease.

However, the ink IK discharged onto the center portion 100 may have a relatively slow drying speed since other ink discharged around the ink IK exists. Accordingly, while the ink IK is discharged onto the center portion 100, the solvent SV may not be discharged.

Further, the ink IK discharged onto the second outer portion 220 may have a relatively slow drying speed since other ink discharged around the ink IK exists. Accordingly, while the ink IK is discharged onto the second outer portion 220, the solvent SV may not be discharged.

In an embodiment, a period in which the solvent SV is discharged may be set based on the vapor pressure around the ink IK discharged onto the substrate SUB (or, the vapor pressure in the chamber CB). For example, as described herein, whether or not the solvent SV is discharged may be set in real time based on the vapor pressure measured by the vapor pressure measurement sensor VPS. Accordingly, a deviation in the drying speed of the ink IK discharged onto the substrate SUB may decrease, and uneven drying of the ink IK may be improved.

In an embodiment, the solvent SV may be discharged together in the chamber CB in which the ink IK is discharged. In other words, the inkjet printing process using the ink IK and a drying delay process using the solvent SV may be performed simultaneously in a single chamber.

In an embodiment, the method may include refraining from ventilating the chamber CB while the ink IK is discharged. Before the ink IK is discharged or after the ink IK is discharged, the chamber CB may be ventilated to remove vapor or mist in the chamber CB. Even if the vapor pressure in the chamber CB increases due to the discharge of the solvent SV, the vapor pressure in the chamber CB may decrease if the chamber CB is ventilated. Accordingly, in order to maintain the vapor pressure in the chamber CB increased by the discharge of the solvent SV, the method may include refraining from ventilating the chamber CB while the ink IK is discharged.

FIGS. 12-14 are diagrams for describing an inkjet printing method according to an embodiment.

Referring to FIG. 12, the inkjet head IH is arranged above the first outer portion 210, and may discharge the ink IK while moving along the first direction D1 (S1121). Accordingly, the ink IK may be discharged onto the first outer portion 210.

In an embodiment, while the ink IK is discharged onto the first outer portion 210, the solvent SV may be discharged from the injection unit IP (S1121). As the solvent SV is discharged, the vapor pressure around the ink IK discharged onto the first outer portion 210 may be controlled. For example, the amount of the solvent SV which is discharged may be increased, and the vapor pressure around the ink IK discharged onto the first outer portion 210 may increase. Accordingly, the drying speed of the ink IK may decrease.

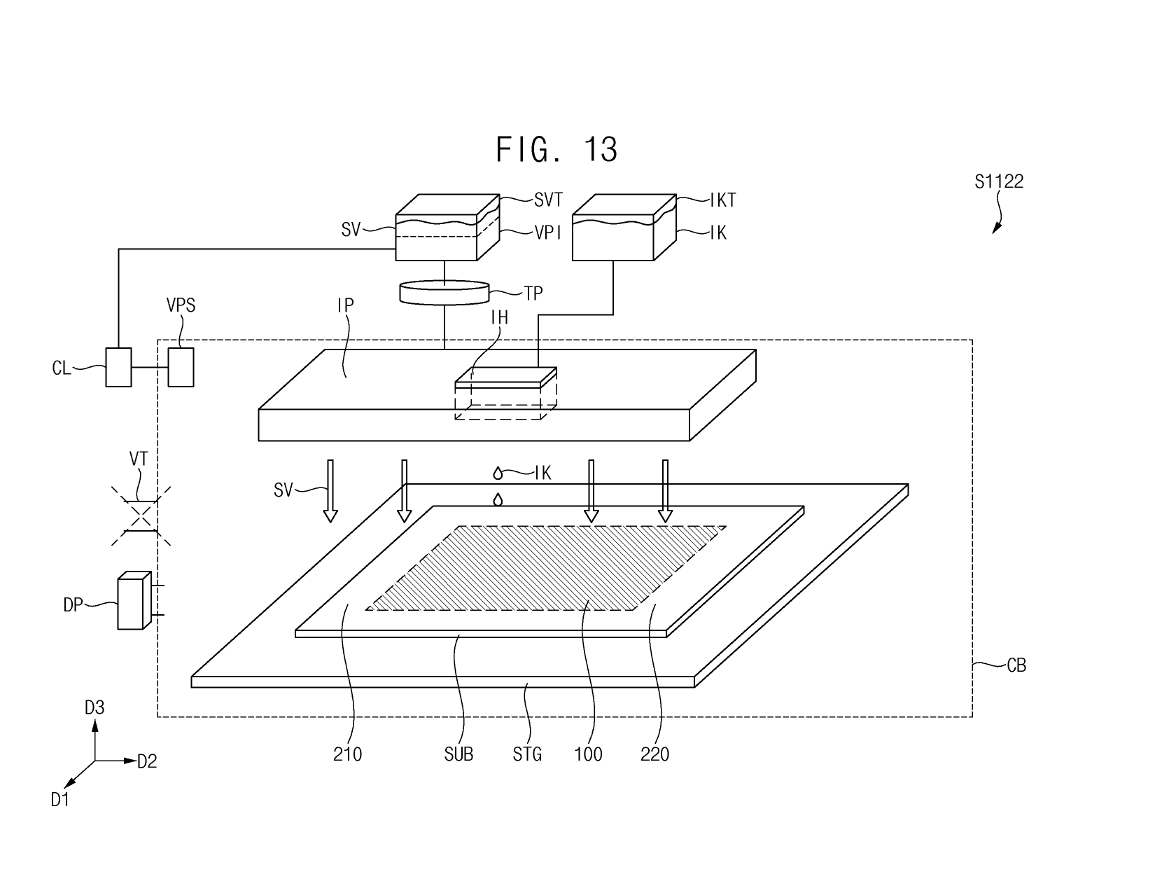

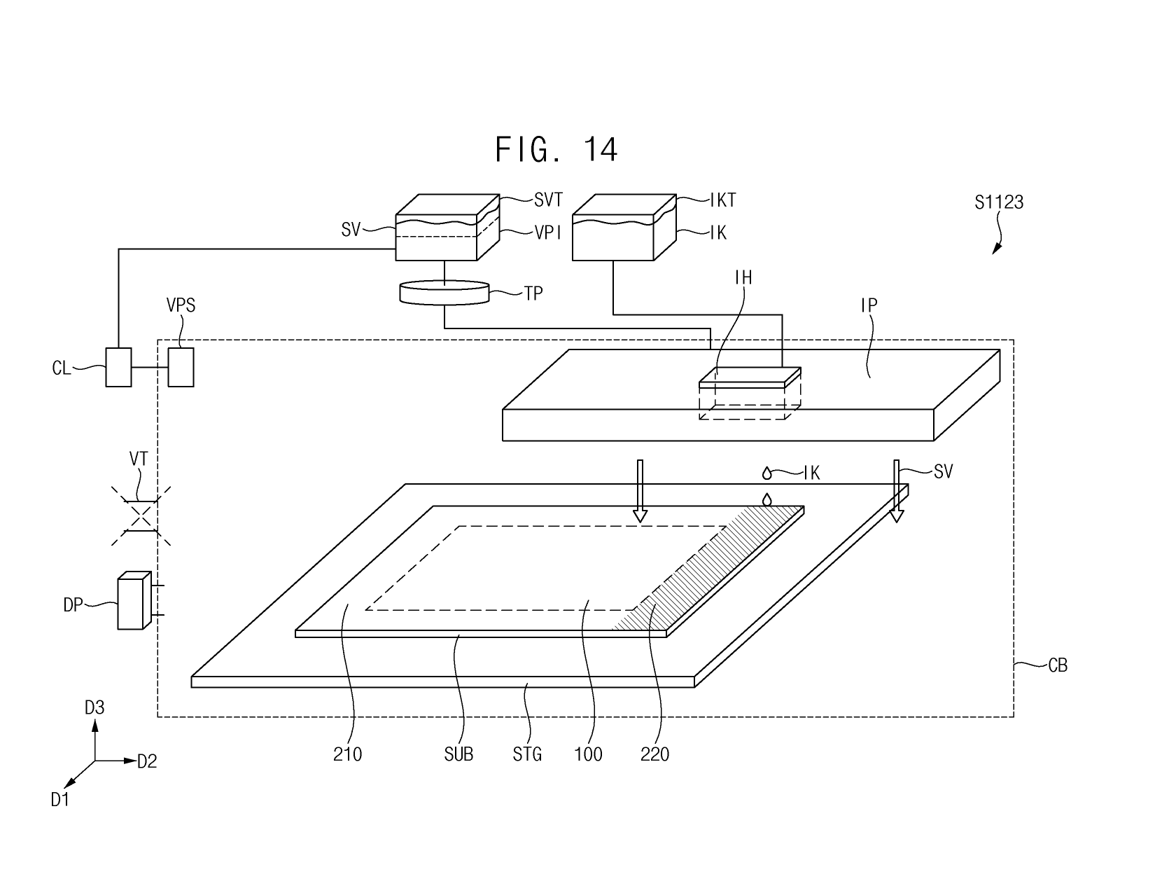

Referring to FIG. 13, after the ink IK is discharged onto the first outer portion 210, the inkjet head IH may be arranged above the center portion 100, and may discharge the ink IK while moving along the first direction D1 (S1122). Accordingly, the ink IK may be discharged onto the center portion 100.

In an embodiment, while the ink IK is discharged onto the center portion 100, the solvent SV may be discharged from the injection portion IP (S1122). As the solvent SV is discharged, the vapor pressure around the ink IK discharged onto the center portion 100 may be controlled.

For example, the amount of the solvent SV discharged while the ink IK is discharged onto the center portion 100 may be less than the amount of the solvent SV discharged while the ink IK is discharged onto the first outer portion 210.

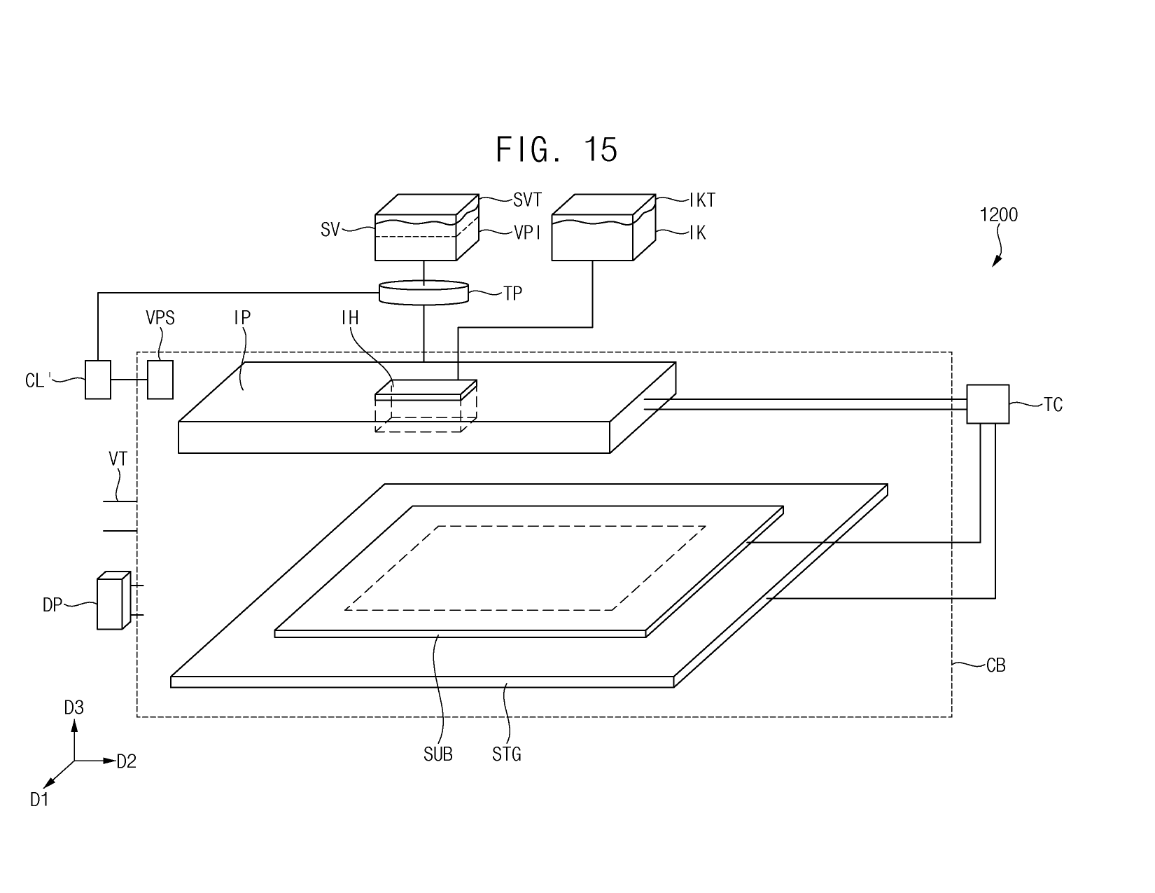

Referring to FIG. 14, after the ink IK is discharged onto the center portion 100, the inkjet head IH may be arranged above the second outer portion 220, and may discharge the ink IK while moving along the first direction D1 (S1123). Accordingly, the ink IK may be discharged onto the second outer portion 220.

In an embodiment, while the ink IK is discharged onto the second outer portion 220, the solvent SV may be discharged from the injection unit IP (S1123). As the solvent SV is discharged, the vapor pressure around the ink IK discharged onto the second outer portion 220 may be controlled.

For example, the amount of the solvent SV discharged while the ink IK is discharged onto the second outer portion 220 may be less than the amount of the solvent SV discharged while the ink IK is discharged onto the center portion 100.

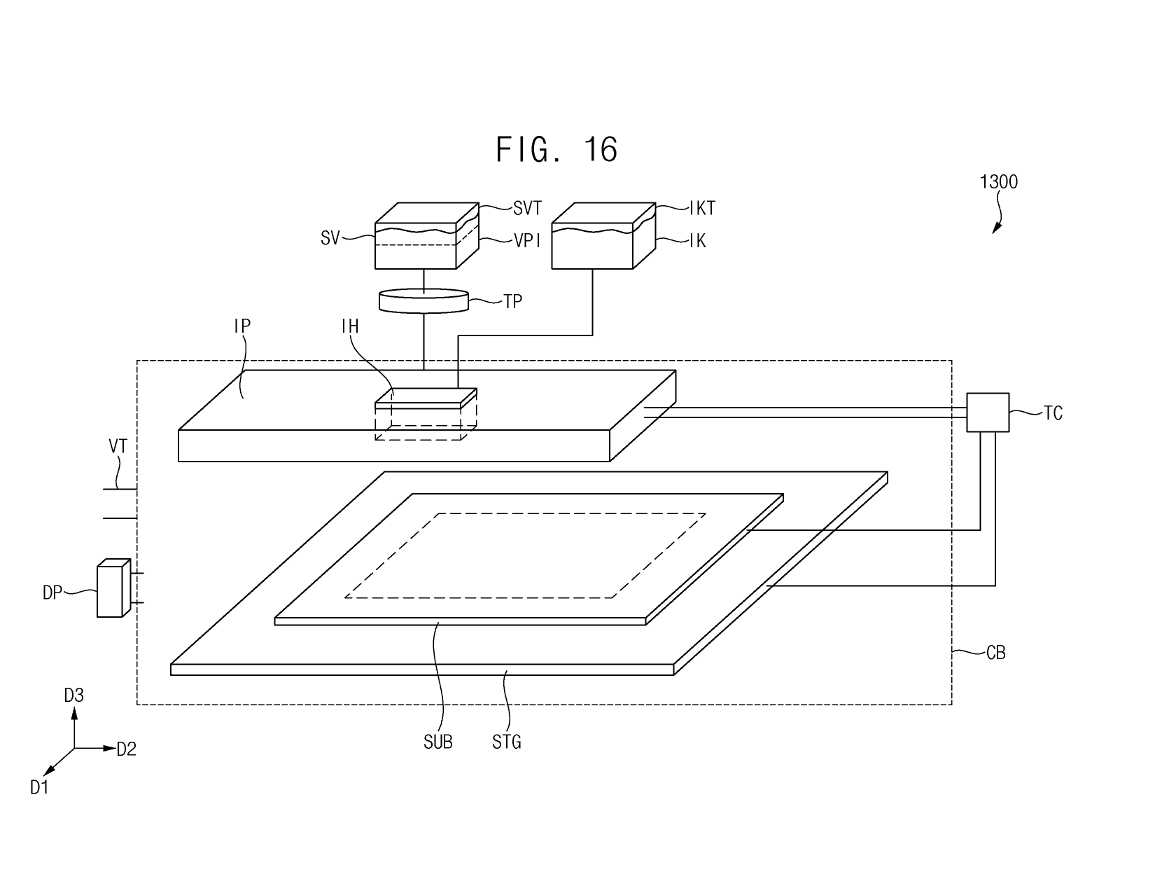

FIG. 15 is a diagram for describing an inkjet printing device according to an embodiment.

Referring to FIG. 15, an inkjet printing device 1200 according to an embodiment of the present disclosure may include an ink storage unit IKT, an inkjet head IH, a solvent storage unit SVT, a vapor pressure increasing unit VPI, a transfer unit TP, an injection unit IP, a recovery unit DP, a temperature control unit TC, a vapor pressure measurement sensor VPS, a solvent control unit CL’, and a ventilation unit VT.

The inkjet printing device 1200 may be substantially the same as the inkjet printing device 1100 described herein with reference to FIG. 1, except for the solvent control unit CL’.

In an embodiment, the solvent control unit CL’ may control the amount of the solvent SV provided to the injection unit IP based on the vapor pressure measured by the vapor pressure measurement sensor VPS. For example, the solvent control unit CL may control the transfer unit TP, and the amount of the solvent SV may be controlled based on the operation of the transfer unit TP.

FIG. 16 is a diagram for describing an inkjet printing device according to an embodiment.

Referring to FIG. 16, an inkjet printing device 1300 according to an embodiment of the present disclosure may include an ink storage unit IKT, an inkjet head IH, a solvent storage unit SVT, a vapor pressure increasing unit VPI, a transfer unit TP, an injection unit IP, a recovery unit DP, a temperature control unit TC, and a ventilation unit VT.

In an embodiment, the inkjet printing device 1300 may be implemented without a vapor pressure measurement sensor and a solvent control unit. For example, the period in which the solvent SV is discharged and the amount of the solvent SV discharged may be preset as applicable or desired.

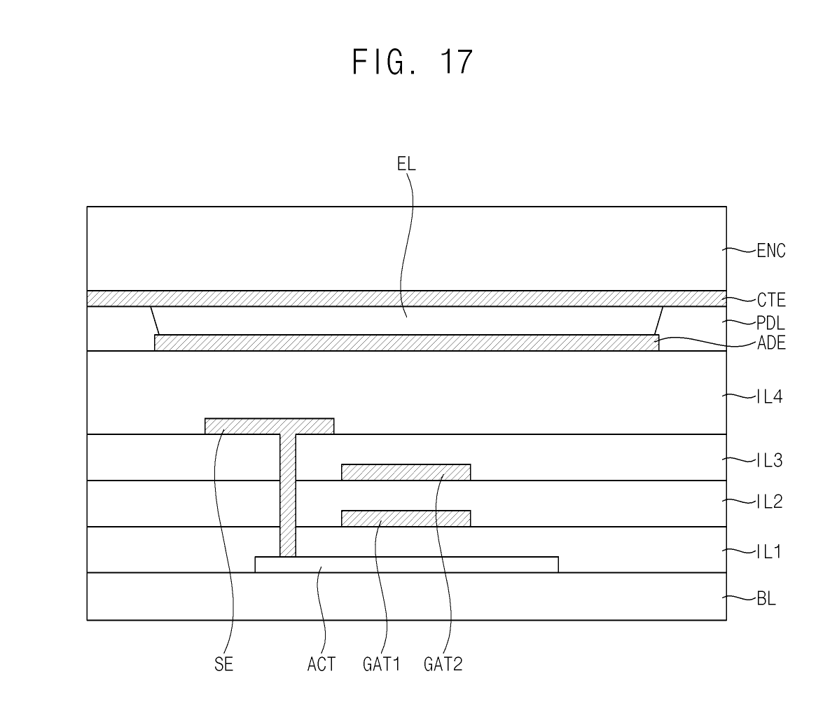

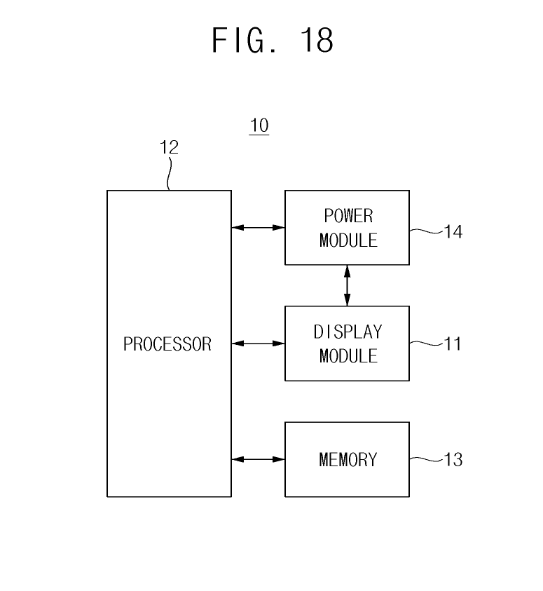

FIG. 17 is a cross-sectional view for describing a display device formed by the inkjet printing device and the inkjet printing method.

Referring to FIG. 17, a base layer BL may be an insulating substrate formed of a transparent or opaque material. In an embodiment, the base layer BL may include glass. In this case, the display device may be a rigid display panel. In an embodiment, the base layer BL may include plastic. In this case, the display device may be a flexible display panel.

An active pattern ACT may be arranged on the base layer BL. In an embodiment, the active pattern ACT may include a silicon semiconductor. For example, the active pattern ACT may include amorphous silicon, polycrystalline silicon, or the like. In an embodiment, the active pattern ACT may include an oxide semiconductor.

A first insulating layer IL1 may cover the active pattern ACT, and may be arranged on the base layer BL. In an embodiment, the first insulating layer IL1 may include an insulating material. For example, the first insulating layer IL1 may include silicon oxide, silicon nitride, silicon oxynitride, or the like.

A first gate electrode GAT1 may be arranged on the first insulating layer IL1, and may overlap the active pattern ACT. In an embodiment, the first gate electrode GAT1 may include a metal, an alloy, a conductive metal oxide, a transparent conductive material, or the like. For example, the first gate electrode GAT1 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. These may be used alone or in combination with each other. Further, the first gate electrode GAT1 may be formed as a single layer or as a multilayer.

A second insulating layer IL2 may cover the first gate electrode GAT1, and may be arranged on the first insulating layer IL1. In an embodiment, the second insulating layer IL2 may include an insulating material. For example, the second insulating layer IL2 may include silicon oxide, silicon nitride, silicon oxynitride, or the like.

A second gate electrode GAT2 may be arranged on the second insulating layer IL2, and may overlap the first gate electrode GAT1. In an embodiment, the second gate electrode GAT2 may include a metal, an alloy, a conductive metal oxide, a transparent conductive material, or the like. For example, the second gate electrode GAT2 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. These may be used alone or in combination with each other. Further, the second gate electrode GAT2 may be formed as a single layer or as a multilayer.

A third insulating layer IL3 may cover the second gate electrode GAT2, and may be arranged on the second insulating layer IL2. In an embodiment, the third insulating layer IL3 may include an insulating material. For example, the third insulating layer IL3 may include silicon oxide, silicon nitride, silicon oxynitride, or the like.

A connection electrode SE may be arranged on the third insulating layer IL3, and may be in contact with the active pattern ACT. In an embodiment, the connection electrode SE may include a metal, an alloy, a conductive metal oxide, a transparent conductive material, or the like. For example, the connection electrode SE may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. These may be used alone or in combination with each other. Further, the connection electrode SE may be formed as a single layer or as a multilayer.

A fourth insulating layer IL4 may cover the connection electrode SE, and may be arranged on the third insulating layer IL3. In an embodiment, the fourth insulating layer IL4 may include an insulating material. For example, the fourth insulating layer IL4 may include photoresist, polyacrylic resin, polyimide resin, acrylic resin, or the like.

A pixel electrode ADE may be arranged on the fourth insulating layer IL4. In an embodiment, the pixel electrode ADE may include a metal, an alloy, a conductive metal oxide, a transparent conductive material, or the like. For example, the pixel electrode ADE may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. These may be used alone or in combination with each other. Further, the pixel electrode ADE may be formed as a single layer or as a multilayer.

A pixel defining layer PDL may be arranged on the fourth insulating layer IL4, and may cover an end of the pixel electrode ADE. In an embodiment, the pixel defining layer PDL may include an insulating material. For example, the pixel definition film PDL may include photoresist, polyacrylic resin, polyimide resin, acrylic resin, or the like.

A light-emitting layer EL may be arranged on the pixel electrode ADE. In an embodiment, the light-emitting layer EL may be formed through the inkjet printing device and the inkjet printing method described herein. For example, the light-emitting layer EL may be formed of ink containing an organic light-emitting material. The light-emitting layer EL may emit light based on a voltage difference between the pixel electrode ADE and a common electrode CTE. Further, the light-emitting layer EL may further include an auxiliary layer such as a hole transport layer, an electron transport layer, or the like.

The common electrode CTE may be arranged on the light-emitting layer EL. In an embodiment, the common electrode CTE may include a metal, an alloy, a conductive metal oxide, a transparent conductive material, or the like. For example, the common electrode CTE may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. These may be used alone or in combination with each other. Further, the common electrode CTE may be formed as a single layer or as a multilayer.

An encapsulation layer ENC may be arranged on the common electrode CTE. The encapsulation layer ENC may prevent oxygen and/or moisture from penetrating into the light-emitting layer EL. In an embodiment, the encapsulation layer ENC may have a structure in which inorganic layers and organic layers are alternately laminated.

The display device according to the embodiment may be applied to various electronic devices. The electronic device according to an embodiment may include the display device described herein, and may further include a module or device having additional functions in addition to the display device.

FIG. 18 is a block diagram illustrating an electronic device according to an embodiment.

Referring to FIG. 18, an electronic device 10 according to an embodiment of the present disclosure may include a display module 11, a processor 12, a memory 13, and a power module 14.

The processor 12 may include at least one of a central processing unit CPU, an application processor AP, a graphic processing unit GPU, a communication processor CP, an image signal processor ISP, and a controller.

The memory 13 may store data information for an operation of the processor 12 or the display module 11. In an example in which the processor 12 executes an application stored in the memory 13, an image data signal and/or an input control signal may be transmitted to the display module 11, and the display module 11 may process the provided signals and output image information through a display screen.

The power module 14 may include a power supply module such as a power adapter, a battery device, or the like and a power conversion module that converts power supplied by the power supply module to generate power for an operation of the electronic device 10.

At least one of the components of the electronic device 10 described herein may be included in the display device according to the embodiments described herein. Further, some of individual modules functionally included in one module may be included in the display device and others may be provided separately from the display device. For example, the display device may include the display module 11, and the processor 12, the memory 13, and the power module 14 may be provided in the form of other devices within the electronic device 11 other than the display device.

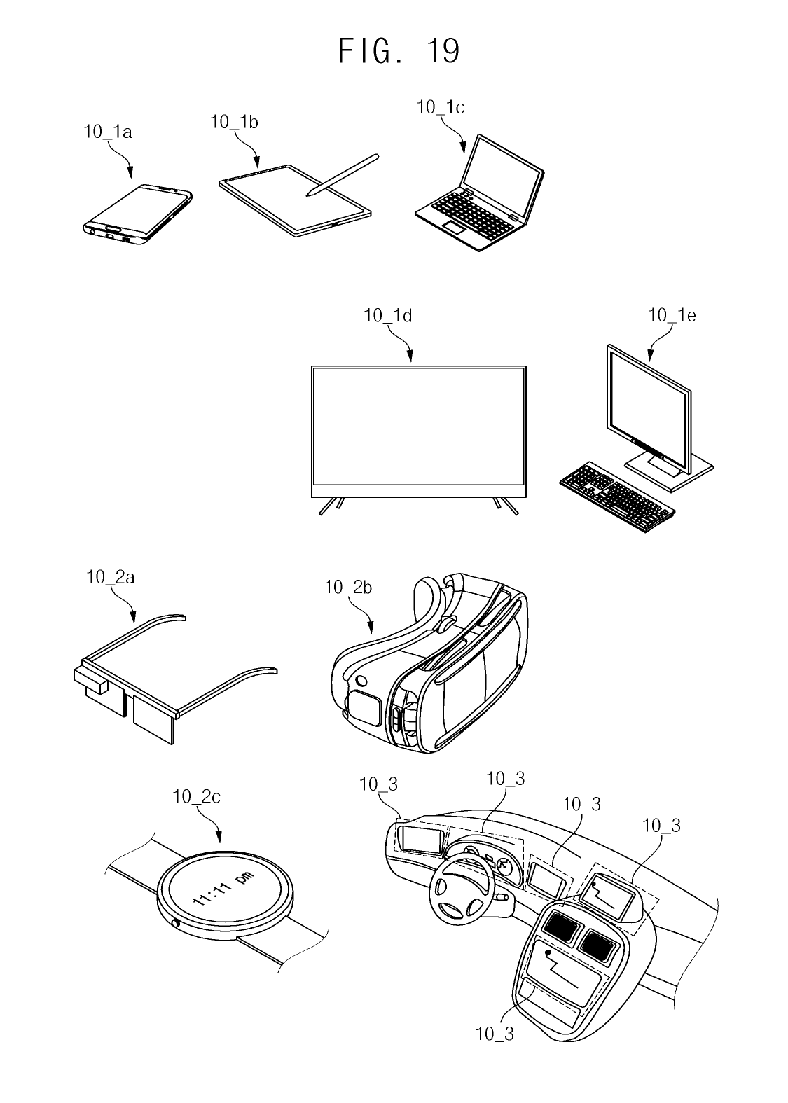

FIG. 19 is a diagram illustrating electronic devices according to embodiments.

Referring to FIG. 19, electronic devices to which display devices according to embodiments are applied may include not only image display electronic devices such as a smart phone 10_1a, a tablet PC 10_1b, a laptop 10_1c, a TV 10_1d, a desk monitor 10_1e, or the like, but also wearable electronic devices including display modules such as smart glasses 10_2a, a head mounted display 10_2b, a smart watch 10_2c, or the like, vehicle electronic devices 10_3 including display modules such as an instrument panel of an automobile, a center fascia, a center information display CID arranged on a dashboard, a room mirror display, or the like.

The embodiments of the present disclosure may be applied to a display device and an electronic device including the display device. For example, the embodiments may be applied to a high-resolution smartphone, a mobile phone, a smart pad, a smart watch, a tablet PC, a vehicle navigation system, a television, a computer monitor, a notebook, or the like.

Although the inkjet printing device and the inkjet printing method according to the embodiments have been described with reference to the drawings, the illustrated embodiments are examples, and may be modified and changed by a person having ordinary knowledge in the relevant technical field without departing from the technical spirit described in the following claims.

What is claimed is:

1. An inkjet printing device, comprising:
an inkjet head which discharges an ink onto a substrate; and
an injection unit which discharges a solvent onto the substrate in association with controlling a vapor pressure around the ink discharged onto the substrate.

2. The inkjet printing device of claim 1, wherein a nozzle which discharges the solvent is formed in the injection unit.

3. The inkjet printing device of claim 1, wherein a slit which discharges the solvent is formed in the injection unit.

4. The inkjet printing device of claim 1, wherein a pore which discharges the solvent is formed in the injection unit.

5. The inkjet printing device of claim 1, wherein the injection unit surrounds a side of the inkjet head.

6. The inkjet printing device of claim 1, further comprising:
a solvent storage unit which stores the solvent;
a vapor pressure increasing unit which increases a vapor pressure of the solvent stored in the solvent storage unit; and
a transfer unit which transfers the solvent having the increased vapor pressure to the injection unit.

7. The inkjet printing device of claim 6, wherein the vapor pressure increasing unit applies heat to the solvent.

8. The inkjet printing device of claim 6, wherein the vapor pressure increasing unit applies an ultrasonic wave to the solvent.

9. The inkjet printing device of claim 6, wherein the transfer unit is a fan or a pump.

10. The inkjet printing device of claim 6, wherein:
the solvent in a liquid state is stored in the solvent storage unit, and
the solvent in a gaseous state is transferred to the injection unit.

11. The inkjet printing device of claim 1, wherein a temperature of the injection unit is higher than or equal to a temperature of the substrate.

12. The inkjet printing device of claim 1, further comprising:
a recovery unit having a temperature lower than a temperature of the substrate and which recovers the solvent by condensation.

13. The inkjet printing device of claim 1, further comprising:
a vapor pressure measurement sensor which measures a vapor pressure around the ink discharged onto the substrate; and
a solvent control unit which controls an amount of the solvent provided to the injection unit based on the measured vapor pressure.

14. The inkjet printing device of claim 1, further comprising:
a ventilation unit which ventilates a chamber in which the substrate is positioned.

15. An inkjet printing method, comprising:
discharging an ink onto a first outer portion of a substrate; and
discharging a solvent onto the substrate in association with controlling a vapor pressure around the ink discharged onto the substrate while the ink is discharged onto the first outer portion of the substrate.

16. The inkjet printing method of claim 15, further comprising:
discharging the ink onto a center portion of the substrate,
wherein the solvent is not discharged while the ink is discharged onto the center portion of the substrate.

17. The inkjet printing method of claim 16, further comprising:
discharging the ink onto a second outer portion of the substrate,
wherein the solvent is not discharged while the ink is discharged onto the second outer portion of the substrate.

18. The inkjet printing method of claim 15, further comprising:
discharging the ink onto a center portion of a substrate; and
discharging the solvent onto the substrate while the ink is discharged onto the center portion of the substrate,
wherein an amount of the solvent discharged while the ink is discharged onto the center portion of the substrate is less than an amount of the solvent discharged while the ink is discharged onto the first outer portion of the substrate.

19. The inkjet printing method of claim 18, further comprising:
discharging the ink onto a second outer portion of a substrate; and
discharging the solvent onto the substrate while the ink is discharged onto the second outer portion of the substrate,
wherein an amount of the solvent discharged while the ink is discharged onto the second outer portion of the substrate is less than the amount of the solvent discharged while the ink is discharged onto the center portion of the substrate.

20. The inkjet printing method of claim 15, wherein a chamber in which the substrate is positioned is not ventilated while the ink is discharged.
